(19) United States
(12) Patent Application Publication
(10) Pub. No.: US 2026/0254454 A1
(43) Pub. Date: Aug. 27, 2026

(54) SYSTEMS AND METHODS OF SOURCE FOLLOWERS AND CONTINUOUS-TIME LINEAR EQUALIZERS FOR HIGH-SPEED INTERFACE CIRCUITS

(71) Applicant: Samsung Electronics Co., Ltd., Suwon-si (KR)

(72) Inventors: Daeho YANG, San Jose, CA (US); KunHung TSAI, San Jose, CA (US); Harinarayan Hari VENKATRAMANI, San Jose, CA (US); Hyunwook KANG, San Diego, CA (US); Shindeok KANG, San Diego, CA (US); Joon Young PARK, San Diego, CA (US)

(21) Appl. No.: 19/236,969

(22) Filed: Jun. 12, 2025

Related U.S. Application Data
(60) Provisional application No. 63/763,252, filed on Feb. 25, 2025.

(51) Int. Cl. H03K 19/0185

(52) U.S. Cl. CPC H03K 19/018521

(57) ABSTRACT

Provided are systems, methods, and apparatuses for circuits for high-speed interfaces (e.g., of memory systems). In one or more examples, the systems, devices, and methods include connecting a first capacitor to an input of the circuit and to an output of the circuit; connecting a first transistor to the input of the circuit; connecting a second transistor to the first transistor and to the output of the circuit; connecting a third transistor to the output of the circuit and the first transistor; and indicating, via the output of the circuit, a logical value based on the input.

### CROSS-REFERENCE TO RELATED APPLICATIONS

This application claims the benefit of U.S. Provisional Patent Application Ser. No. 63/763,252, filed Feb. 25, 2025, which is incorporated by reference herein for all purposes.

### TECHNICAL FIELD

The disclosure relates generally to integrated circuits of memory systems. In particular, the subject matter relates to circuits for high-speed interfaces (e.g., of memory systems), where the circuits may be based on a flipped-voltage-follower (FVF) source follower (SF) continuous-time linear equalizer (CTLE).

### BACKGROUND

Memory systems can include double data rate (DDR) memory. DDR memory can include a type of computer memory that allows for faster data transfer rates by transferring data on both the rising and falling edges of a clock signal, doubling the data transfer rate compared to other memory technologies that only used one edge of the clock signal. DDR memory can be used in computers, mobile devices, and servers to improve system performance and multitasking capabilities. DDR memory can include synchronous dynamic random-access memory (SDRAM). Circuits used in DDR memory can include memory cells (e.g., storage capacitor and transistor), data latches, address decoders, control logic circuits, input/output buffers, termination circuits, etc. Signals used in DDR memory can include a clock signal (CK) that provides a timing reference for data transfer, data strobe signal (DQS) that can indicate the valid data window, chip select (CS) that enables a specific memory chip, and command signals that can include instructions like read, write, etc.

### SUMMARY

In various embodiments, the systems and methods described herein include systems, methods, and apparatuses of a hybrid circuit based on flipped-voltage-follower (FVF) source follower (SF) circuitry combined with continuous-time linear equalizer (CTLE) circuitry. In some aspects, the techniques described herein relate to a circuit including: a first capacitor connected to an input of the circuit and to an output of the circuit; a first transistor connected to the input of the circuit; a second transistor connected to the first transistor and to the output of the circuit; a third transistor connected to the output of the circuit and the first transistor; and the output of the circuit indicating a logical value based on the input.

In some aspects, the techniques described herein relate to a circuit, wherein: a gate terminal of the first transistor is connected to the input of the circuit and the first capacitor, and a drain terminal of the first transistor is connected to a source terminal of the second transistor.

In some aspects, the techniques described herein relate to a circuit, wherein the second transistor is configured as a variable resistor.

In some aspects, the techniques described herein relate to a circuit, wherein decreasing a resistor level of the second transistor decreases a direct current (DC) gain at the output of the circuit.

In some aspects, the techniques described herein relate to a circuit, wherein: a gate terminal of the second transistor is connected to an enable control signal, and a drain terminal of the second transistor is connected to the output of the circuit, the first capacitor, and a source terminal of the third transistor.

In some aspects, the techniques described herein relate to a circuit, wherein a drain terminal of the third transistor is connected to a positive supply voltage of the circuit.

In some aspects, the techniques described herein relate to a circuit, further including a fourth transistor connected to the first transistor and the third transistor.

In some aspects, the techniques described herein relate to a circuit, wherein: a gate terminal of the fourth transistor is connected to an N-type metal oxide semiconductor (NMOS) bias voltage of the circuit, a drain terminal of the fourth transistor is connected to a source terminal of the first transistor and to a gate terminal of the third transistor, and a source terminal of the fourth transistor is connected to ground.

In some aspects, the techniques described herein relate to a circuit, wherein the first capacitor is configured as a high-pass filter that attenuates direct current (DC) signals from the input of the circuit to the output of the circuit and allows alternating current (AC) signals to pass from the input of the circuit to the output of the circuit.

In some aspects, the techniques described herein relate to a circuit, wherein the input of the circuit includes a voltage level of a memory cell.

In some aspects, the techniques described herein relate to a circuit, wherein an alternating current (AC) gain at the output of the circuit is determined from a quotient based on a capacitance of the first capacitor and a load capacitance at the output of the circuit.

In some aspects, the techniques described herein relate to a circuit of a memory device including: a first capacitor connected to an input of the circuit and to an output of the circuit; a first transistor connected to the input of the circuit; a second transistor connected to the first transistor and to the output of the circuit; a third transistor connected to the output of the circuit and the first transistor; a fourth transistor connected to the first transistor; and the output of the circuit indicating a logical value of a memory cell of the memory device.

In some aspects, the techniques described herein relate to a circuit, wherein: a gate terminal of the fourth transistor is connected to an N-type metal oxide semiconductor (NMOS) bias voltage of the circuit, and a source terminal of the fourth transistor is connected to ground.

In some aspects, the techniques described herein relate to a circuit, further including a fifth transistor, wherein: a gate terminal of the fifth transistor is connected to a P-type metal oxide semiconductor (PMOS) bias voltage of the circuit, and a drain terminal of the fifth transistor and a drain terminal of the third transistor are connected to a positive supply voltage of the circuit.

In some aspects, the techniques described herein relate to a circuit, further including a sixth transistor, wherein: a drain terminal of the sixth transistor is connected to a gate of the third transistor and a source of the fifth transistor; a gate terminal of the sixth transistor is connected to a source of the first transistor and the drain of the fourth transistor, and a source terminal of the sixth transistor is connected to ground.

In some aspects, the techniques described herein relate to a memory system including a circuit, the circuit including: a first capacitor connected to an input of the circuit and to an output of the circuit; a first transistor connected to the input of the circuit; a second transistor connected to the first transistor and to the output of the circuit; a third transistor connected to the output of the circuit and the second transistor; and the output of the circuit indicating a logical value of a memory cell.

In some aspects, the techniques described herein relate to a circuit, further including a fourth transistor, wherein: a gate terminal of the fourth transistor is connected to an N-type metal oxide semiconductor (NMOS) bias voltage of the circuit, a drain terminal of the fourth transistor is connected to a source terminal of the first transistor and to a gate terminal of the third transistor, and a source terminal of the fourth transistor is connected to ground.

In some aspects, the techniques described herein relate to a circuit, further including a fifth transistor, wherein: a gate terminal of the fifth transistor is connected to an enable control signal, a drain terminal of the fifth transistor is connected to a positive supply voltage of the circuit, and a source terminal of the fifth transistor is connected to a drain of the third transistor.

In some aspects, the techniques described herein relate to a circuit, wherein the third transistor and the fifth transistor are configured as respective variable resistors.

In some aspects, the techniques described herein relate to a circuit, wherein the input of the circuit includes a voltage level of a memory cell.

The systems and methods described herein may provide multiple advantages and benefits. For example, the systems and methods described herein may provide flipped-voltage-follower source follower and continuous-time linear equalizer (FVF-SF-CTLE) circuit designs that improve system performance. For instance, the FVF-SF-CTLE circuit designs described herein increase bandwidth compared to other systems. Also, the FVF-SF-CTLE circuit designs described herein reduce current usage and reduce the circuit area (e.g., surface area of a printed circuit board).

### BRIEF DESCRIPTION OF THE DRAWINGS

The above-mentioned aspects and other aspects of the present systems and methods will be better understood when the present application is read in view of the following figures in which like numbers indicate similar or identical elements. Further, the drawings provided herein are for purpose of illustrating certain embodiments only; other embodiments, which may not be explicitly illustrated, are not excluded from the scope of this disclosure.

These and other features and advantages of the present disclosure will be appreciated and understood with reference to the specification, claims, and appended drawings, wherein:

FIG. 1 illustrates an example system in accordance with one or more implementations as described herein.

FIG. 2 illustrates an example system in accordance with one or more implementations as described herein.

FIG. 3 illustrates an example circuit in accordance with one or more implementations as described herein.

FIG. 4 illustrates an example circuit in accordance with one or more implementations as described herein.

FIG. 5 illustrates an example circuit in accordance with one or more implementations as described herein.

While the present systems and methods are susceptible to various modifications and alternative forms, specific embodiments thereof are shown by way of example in the drawings and will herein be described. The drawings may not be to scale. It should be understood, however, that the drawings and detailed description thereto are not intended to limit the present systems and methods to the particular form disclosed, but to the contrary, the intention is to cover all modifications, equivalents, and alternatives falling within the spirit and scope of the present systems and methods as defined by the appended claims.

### DETAILED DESCRIPTION OF VARIOUS EMBODIMENTS

The details of one or more embodiments of the subject matter described herein are set forth in the accompanying drawings and the description below. Other features, aspects, and advantages of the subject matter will become apparent from the description, the drawings, and the claims.

Various embodiments of the present disclosure now will be described more fully hereinafter with reference to the accompanying drawings, in which some, but not all embodiments are shown. Indeed, the disclosure may be embodied in many forms and should not be construed as limited to the embodiments set forth herein; rather, these embodiments are provided so that this disclosure will satisfy applicable legal requirements. The term “or” is used herein in both the alternative and conjunctive sense, unless otherwise indicated. The terms “illustrative” and “example” are used to be examples with no indication of quality level. Like numbers refer to like elements throughout. Arrows in each of the figures depict bi-directional data flow and/or bi-directional data flow capabilities. The terms “path,” “pathway” and “route” are used interchangeably herein.

Embodiments of the present disclosure may be implemented in various ways, including as computer program products that comprise articles of manufacture. A computer program product may include a non-transitory computer-readable storage medium storing applications, programs, program components, scripts, source code, program code, object code, byte code, compiled code, interpreted code, machine code, executable instructions, and/or the like (also referred to herein as executable instructions, instructions for execution, computer program products, program code, and/or similar terms used herein interchangeably). Such non-transitory computer-readable storage media includes all computer-readable media (including volatile and non-volatile media).

As should be appreciated, various embodiments of the present disclosure may be implemented as methods, apparatus, systems, computing devices, computing entities, and/or the like. As such, embodiments of the present disclosure may take the form of an apparatus, system, computing device, computing entity, and/or the like executing instructions stored on a computer-readable storage medium to perform certain steps or operations. Thus, embodiments of the present disclosure may take the form of a hardware embodiment, a computer program product embodiment, and/or an embodiment that comprises a combination of computer program products and hardware performing certain steps or operations.

Embodiments of the present disclosure are described below with reference to block diagrams and flowchart illustrations. Thus, it should be understood that each block of the block diagrams and flowchart illustrations may be implemented in the form of a computer program product, a hardware embodiment, a combination of hardware and computer program products, and/or apparatus, systems, computing devices, computing entities, and/or the like carrying out instructions, operations, steps, and similar words used interchangeably (for example the executable instructions, instructions for execution, program code, and/or the like) on a computer-readable storage medium for execution. For example, retrieval, loading, and execution of code may be performed sequentially, such that one instruction is retrieved, loaded, and executed at a time. In some example embodiments, retrieval, loading, and/or execution may be performed in parallel, such that multiple instructions are retrieved, loaded, and/or executed together. Thus, such embodiments can produce specifically configured machines performing the steps or operations specified in the block diagrams and flowchart illustrations. Accordingly, the block diagrams and flowchart illustrations support various combinations of embodiments for performing the specified instructions, operations, or steps.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not be necessarily all referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms, and a plural term may include the corresponding singular form. Similarly, a hyphenated term (e.g., “two-dimensional,” “pre-determined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms, and a plural term may include the corresponding singular form. It is further noted that various figures (including component diagrams) shown and discussed herein are for illustrative purpose only, and are not drawn to scale. Similarly, various waveforms and timing diagrams are shown for illustrative purpose only. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “module” refers to any combination of software, firmware and/or hardware configured to provide the functionality described herein in connection with a module. For example, software may be embodied as a software package, code and/or instruction set or instructions, and the term “hardware,” as used in any implementation described herein, may include, for example, singly or in any combination, an assembly, hardwired circuitry, programmable circuitry, state machine circuitry, and/or firmware that stores instructions executed by programmable circuitry. The modules may, collectively or individually, be embodied as circuitry that forms part of a larger system, for example, but not limited to, an integrated circuit (IC), system on chip (SoC), an assembly, and so forth

The provided description is presented to enable one of ordinary skill in the art to make and use the subject matter disclosed herein and to incorporate it in the context of particular applications. While the following is directed to specific examples, other and further examples may be devised without departing from the basic scope thereof.

Various modifications, as well as a variety of uses in different applications, will be readily apparent to those skilled in the art, and the general principles defined herein may be applied to a wide range of embodiments. Thus, the subject matter disclosed herein is not intended to be limited to the embodiments presented, but is to be accorded the widest scope consistent with the principles and novel features disclosed herein.

In the description provided, numerous specific details are set forth in order to provide a more thorough understanding of the subject matter disclosed herein. It will, however, be apparent to one skilled in the art that the subject matter disclosed herein may be practiced without necessarily being limited to these specific details. In other instances, well-known structures and devices are shown in block diagram form, rather than in detail, in order to avoid obscuring the subject matter disclosed herein.

All the features disclosed in this specification (e.g., any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

Various features are described herein with reference to the figures. It should be noted that the figures are only intended to facilitate the description of the features. The various features described are not intended as an exhaustive description of the subject matter disclosed herein or as a limitation on the scope of the subject matter disclosed herein. Additionally, an illustrated example need not have all the aspects or advantages shown. An aspect or an advantage described in conjunction with a particular example is not necessarily limited to that example and can be practiced in any other examples even if not so illustrated, or if not so explicitly described.

Furthermore, any element in a claim that does not explicitly state “means for” performing a specified function, or “step for” performing a specific function, is not to be interpreted as a “means” or “step” clause as specified in 35 U.S.C. Section 112, Paragraph 6. In particular, the use of “step of” or “act of” in the Claims herein is not intended to invoke the provisions of 35 U.S.C. 112, Paragraph 6.

It is noted that, if used, the labels left, right, front, back, top, bottom, forward, reverse, clockwise and counterclockwise have been used for convenience purposes only and are not intended to imply any particular fixed direction. Instead, the labels are used to reflect relative locations and/or directions between various portions of an object.

Moreover, the terms “system,” “component,” “module,” “interface,” “model,” or the like are generally intended to refer to a computer-related entity, either hardware, a combination of hardware and software, software, or software in execution. For example, a component may be, but is not limited to being, a process running on a processor, a processor, an object, an executable, a thread of execution, a program, and/or a computer. By way of illustration, both an application running on a controller and the controller can be a component. One or more components may reside within a process and/or thread of execution and a component may be localized on one computer and/or distributed between two or more computers.

Unless explicitly stated otherwise, each numerical value and range may be interpreted as being approximate, as if the word “about” or “approximately” preceded the value of the value or range. Signals and corresponding nodes or ports might be referred to by the same name and are interchangeable for purposes here.

While embodiments may have been described with respect to circuit functions, the embodiments of the subject matter disclosed herein are not limited. Possible implementations may be embodied in a single integrated circuit, a multi-chip module, a single card, SoC, or a multi-card circuit pack. As would be apparent to one skilled in the art, the various embodiments might also be implemented as part of a larger system. Such embodiments may be employed in conjunction with, for example, a digital signal processor, microcontroller, field-programmable gate array, application-specific integrated circuit, or general-purpose computer.

With some systems, the receiver input path can have signal degradation based on the relatively long length connection, which can limit bandwidth. The hybrid circuit designs described herein can increase this bandwidth. For example, the systems and methods described herein may be based on a hybrid circuit that can provide an equalization function (e.g., provide a high-pass filter (HPF) effect based on CTLE circuitry) that can increase this bandwidth and provide a higher output voltage level (e.g., for NMOS input samplers).

With some systems, a source follower and CTLE function can be configured separately, which can consume a relatively large amount of current and take up a relatively large area of a circuit. The hybrid circuit designs described herein reduce the current that is consumed while also reducing the circuit area. (e.g., level-up shifter function).

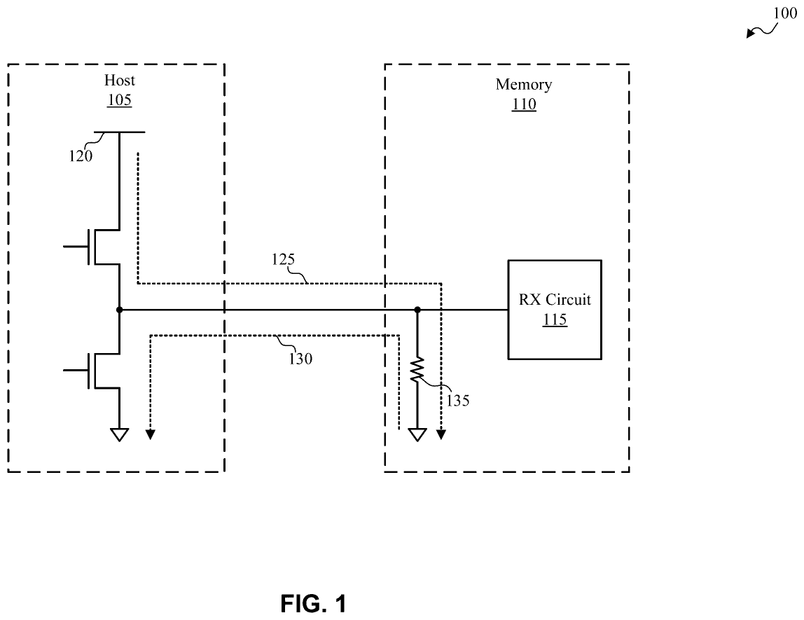

FIG. 1 illustrates an example system 100 in accordance with one or more implementations as described herein. In some configurations, one or more aspects of system 100 may be implemented by or in conjunction with a hybrid circuit. System 100 may include and/or may be based on high-speed memory interfaces. For example, system 100 may be based on or may incorporate a hybrid circuit based on flipped-voltage-follower (FVF) and source follower (SF) circuitry and continuous-time linear equalizer (CTLE) circuitry configured for high-speed interfaces (e.g., of memory systems). In some cases, high-speed memory interfaces can include double data rate (DDR), graphics double data rate (GDDR), high bandwidth memory (HBM), low power double data rate (LPDDR), etc.

In the illustrated example, system 100 may include host 105 and memory 110. Memory 110 may include a receiver (RX) circuit 115 (e.g., DDR receiver circuit) and resistor 135. As shown, system 100 may include charging path 125 from host 105 to memory 110 and discharging path 130 from memory 110 to host 105.

Host 105 may include any computing system. Host 105 may be termed a machine, a device, host, a system, or a server. Host 105 may include a data center server, rack server, a blade server, a desktop computer, a tower computer, a mini tower computer, a desktop server, a laptop computer, a notebook computer, a tablet computer, etc. Memory 110 may include any variety of memory, such as flash memory, Dynamic Random Access Memory (DRAM), Static Random Access Memory (SRAM), Persistent Random Access Memory, Ferroelectric Random Access Memory (FRAM), or Non-Volatile Random Access Memory (NVRAM), such as Magnetoresistive Random Access Memory (MRAM), Phase Change Memory (PCM), or Resistive Random-Access Memory (ReRAM). Memory 110 may include volatile and/or non-volatile memory. Memory 110 may use any desired form factor: for example, Single In-Line Memory Module (SIMM), Dual In-Line Memory Module (DIMM), Non-Volatile DIMM (NVDIMM), etc. Memory 110 may be any desired combination of different memory types, and may be managed by a memory controller.

As shown, host 105 may include one or more transistors. A first transistor of host 105 may connect to a voltage source of host 105 (e.g., voltage reference 120). Voltage reference 120 may provide a VDD voltage for system 100 (e.g., 500 mV). The first transistor of host 105 may connect to a second transistor of host 105. As shown, the second transistor of host 105 may connect to ground.

In some cases, VDD can refer to a positive supply voltage of a circuit (e.g., voltage reference 120), while VSS can refer to ground or the negative supply voltage. VDDQ (e.g., data output power) can refer to the power supply for the data input/output (DQ) pins of the device, enabling the device to drive the load connected to the data input/output (DQ) pins. VSSQ (e.g., data output ground) can serve as the ground reference for the data input/output (DQ) pins, or the return path for the current flowing through the DQ pins. Accordingly, VDD/VSS may be associated with power supply for the internal circuits of a device, while VDDQ/VSSQ may be associated with power supply for the data bus I/O pin drivers of the device.

A node between the first transistor and second transistor of host 105 may connect to memory 110 (e.g., connect to an input of RX circuit 115 via a receiver input path). As shown, the input of RX circuit 115 may connect to resistor 135 of memory 110, where resistor 135 is connected to ground of memory 110. Resistor 135 may be configured with some resistance value (e.g., 60 ohms). In some cases, host 105 may be configured as a host transmitter of memory 110. Memory 110 may depict a DRAM transmitter for on-die termination (ODT).

In the illustrated example, memory 110 may depict aspects of a write mode of a memory device (e.g., DRAM). Host 105 may provide a charge to memory 110 via charging path 125. As shown, charging path 125 may travel from voltage reference 120 of host 105 to ground of memory 110. Charging path 125 may be configured with some impedance (e.g., 35 ohms). As shown, system 100 may include discharging path 130, which may run from ground of memory 110 to ground of host 105. Discharging path 130 may be configured with some impedance (e.g., 35 ohms).

In some examples, RX circuit 115 may be configured for receiving and processing data signals from a memory controller (e.g., DRAM controller) or other devices. RX circuit 115 may be configured to provide accurate data retrieval and storage. In some cases, RX circuit 115 may receive data signals (e.g., DQ, DQS) transmitted from a memory controller and convert the data signals into a usable format (e.g., for a DRAM memory core). RX circuit 115 may include circuits to handle high-speed data transfer and mitigate signal impairments. RX circuit 115 can include circuitry (e.g., on the memory controller, on a memory chip) that is configured for receiving incoming data signals from a memory module, interpreting the data based on a clock signal, and transferring the interpreted data to internal processing units. For example, RX circuit 115 may detect and interpret data signals transmitted from host 105, ensuring accurate data transfer and preventing errors.

In some cases, system 100 may use VSSQ termination, which can provide a stable reference voltage for data lines by connecting the data lines to a dedicated ground plane, leading to better signal quality. In some cases, RX circuit 115 may include one or more input samplers (e.g., N-type metal oxide semiconductor (NMOS), P-type MOS (PMOS)).

The voltage level of an input signal to an NMOS transistor is generally higher than that of a PMOS transistor. However, NMOS transistors are generally faster than PMOS transistors because electrons, the charge carriers in NMOS, have higher mobility than holes, the charge carriers in PMOS. Accordingly, the systems and methods described herein may provide a hybrid circuit to provide a higher common mode voltage (e.g., provide higher voltage levels for NMOS input samplers based on source follower (SF) circuitry). Common-mode voltage may refer to the voltage that is equal or relatively the same on both sides of a differential pair (e.g., two-wire signal, NMOS input pair) relative to a common ground. A common-mode voltage can suppress unwanted noise.

With some systems, a receiver input signal (e.g., input signal of RX circuit 115) can have disadvantages based on VSSQ termination and signal degradation from channel loss. The VSSQ termination can have a voltage level that is too low to operate an NMOS input pair (e.g., NMOS input sampler) of RX circuit 115. The hybrid circuit designs described herein can provide higher voltage levels for NMOS input samplers.

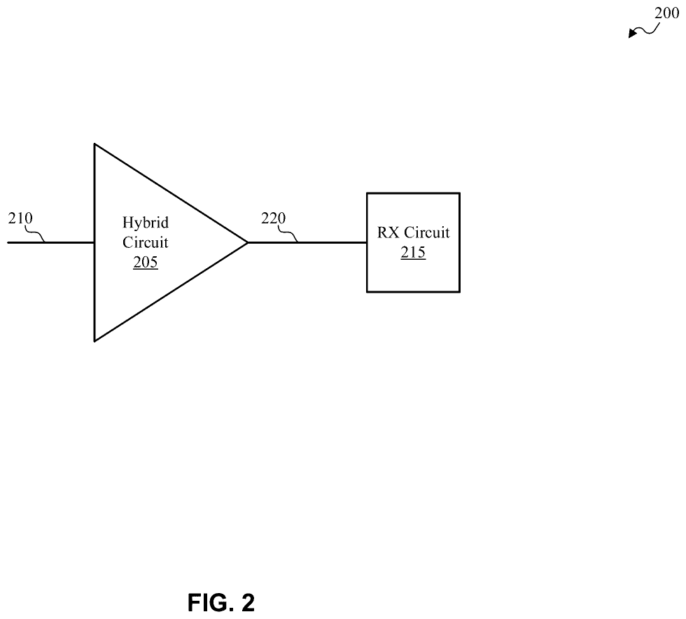

FIG. 2 illustrates an example system 200 in accordance with one or more implementations as described herein. In some configurations, one or more aspects of system 200 may be implemented by or in conjunction with a hybrid circuit. For example, system 200 may be based on or may incorporate a hybrid circuit based on flipped-voltage-follower (FVF) source follower (SF) continuous-time linear equalizer (CTLE) configured for high-speed interfaces (e.g., of memory systems, DDR, etc.). Hybrid circuit 205 may be implemented in host 105 and/or in memory 110.

In the illustrated example, system 200 may include hybrid circuit 205 and RX circuit 215. As shown, system 200 may include input 210 of hybrid circuit 205 and output 220 of hybrid circuit 205. As shown, output 220 may be an input of RX circuit 215. RX circuit 215 may be an example of RX circuit 115. In some configurations, one or more aspects of the systems and methods described herein may be implemented by or in conjunction with hybrid circuit 205.

In some examples, hybrid circuit 205 may be based on and/or incorporate flipped-voltage-follower (FVF) and source follower (SF) circuitry and continuous-time linear equalizer (CTLE) circuitry. Hybrid circuit 205 may be configured for high-speed interfaces (e.g., of memory systems). The input of an input sampler of RX circuit 215 may be data from output 220 of hybrid circuit 205. The input sampler may include a clock signal and the input sampler may determine whether the data is high (e.g., logical 1) or low (e.g., logical 0).

The systems and methods described may include and/or may be based on continuous time linear equalizers (CTLEs). CTLEs can include a type of electronic filter used at the receiver side of a data transmission channel to compensate for signal losses at high frequencies by boosting those frequencies, improving the signal quality by evening out the frequency response of the channel. With some systems, CTLE circuitry may not include source follower circuitry. In some examples, a CTLE of hybrid circuit 205 may be configured as a high-pass filter (HPF), where the gain of the CTLE circuit increases as frequency increases.

In some examples, hybrid circuit 205 may include and/or may be based on source follower (SF) circuitry. SF circuitry may be configured as a buffer stage, providing a high input impedance and low output impedance, isolating the signal source from the load and ensuring signal integrity during data transmission (e.g., on a DDR bus). The SF may be configured as a common drain amplifier where the output is taken from the source of the transistor, hence “source follower.” In some systems, the source follower (SF) may provide a relatively wide bandwidth. The SF of some systems may provide a relatively wide bandwidth for high-speed operation, but may lack CTLE circuitry.

With some circuits, there can be a relatively high level of parasitic capacitance. This parasitic capacitance, when combined with resistances or inductances, can indeed cause low-pass filter (LPF) characteristics in the circuit, resulting in the circuit producing a relatively flat frequency response for lower frequencies, and signal attenuation at higher frequencies. CTLE can increase operational bandwidth of hybrid circuit 205. Thus, hybrid circuit 205 may be configured with CTLE circuitry to increase the operational bandwidth of hybrid circuit 205. CTLE can add a high-pass filter (HPF) component to hybrid circuit 205. The HPF of the CTLE circuitry combined with the LPF characteristics of hybrid circuit 205 can increase the bandwidth of hybrid circuit 205. Accordingly, hybrid circuit 205 may include CTLE circuitry to add a HPF characteristics to hybrid circuit 205, where the effect of the LPF characteristics of hybrid circuit 205 combined with the HPF of the CTLE circuitry can provide a wider operational bandwidth (e.g., increase the flat region in the gain of the output of hybrid circuit 205).

In some cases, hybrid circuit 205 may include and/or may be based on flip voltage followers (FVFs). FVFs can include a circuit configured as a voltage buffer based on a flipped transistor configuration, resulting in a relatively low output impedance, making the FVF useful for low-power and low-voltage applications. With FVFs, the input may be connected to the gate of the transistor while the output may be taken from the source, unlike a source follower, where the input is on the source and output on the drain. A source follower (SF) can provide a relatively wide bandwidth, but may benefit from wider bandwidths for high-speed operation of NMOS input pairs. Also, some SF circuits can experience bandwidth limitations for high-frequency operation. However, FVF circuitry can lower output impedance, which can increase operational bandwidth for a given circuit. Accordingly, hybrid circuit 205 may include SF and FVF circuitry.

Based on the systems and methods described herein, hybrid circuit 205 provides a higher voltage common mode based on SF/FVF aspects of hybrid circuit 205 and provides an equalization function that increases the operational bandwidth based on CTLE aspects of hybrid circuit 205. For example, hybrid circuit 205 can increase the input voltage (e.g., 0 mv to 310 mv) to a higher voltage (e.g., VDDQ/2 to VDDQ) for the relatively high-speed operation associated with NMOS input samplers (e.g., of RX circuit 215).

Based on the systems and methods described herein, hybrid circuit 205 may provide a level up shifter for high-speed operation, increasing an output voltage of hybrid circuit 205 (e.g., for NMOS input sampler of RX circuit 215). Hybrid circuit 205 may provide CTLE circuitry that adds the HPF function to hybrid circuit 205, countering LPF characteristics of hybrid circuit 205 to increase the operational bandwidth of hybrid circuit 205. The increased output voltage and increased operational bandwidth provides a cleaner output in spite of a noisy input. Thus, hybrid circuit 205 improves the ability of an input sampler of RX circuit 215 in determining whether the input data is a logical 0 or logical 1 based on a stream of data being provided by hybrid circuit 205 to RX circuit 215 at a relatively high rate.

Accordingly, hybrid circuit 205 may receive a relatively low input voltage and provide a relatively high output voltage (e.g., relatively high common-mode voltage for NMOS input pair of RX circuit). Also, hybrid circuit 205 may add a high-pass filter (e.g., via CTLE) to increase the operational bandwidth of hybrid circuit 205 (e.g., increase the bandwidth of the flat region of the frequency response of hybrid circuit 205).

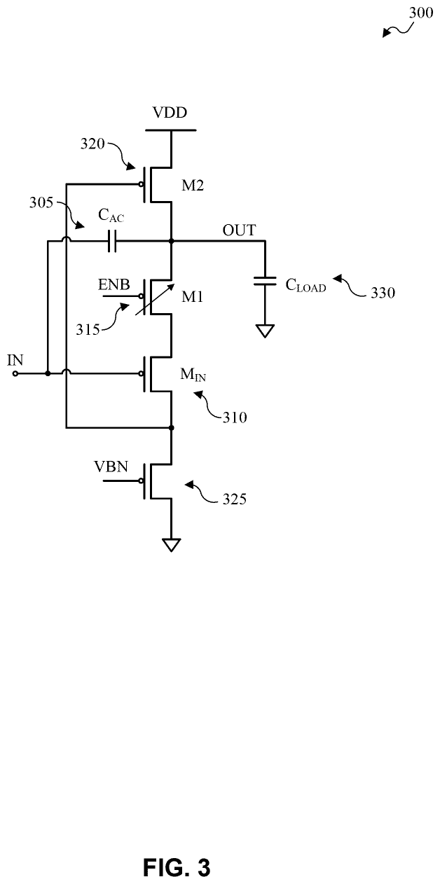

FIG. 3 illustrates an example circuit 300 in accordance with one or more implementations as described herein. In some configurations, one or more aspects of circuit 300 may be implemented by or in conjunction with a hybrid circuit (e.g., hybrid circuit 205). For example, circuit 300 may be based on or may incorporate a hybrid circuit based on flipped-voltage-follower (FVF) source follower (SF) continuous-time linear equalizer (CTLE) configured for high-speed interfaces (e.g., of memory systems, DDR, etc.). In some cases, circuit 300 may be an example of hybrid circuit 205 of FIG. 2.

In some cases, circuit 300 may include one or more transistors (e.g., metal-oxide-semiconductor field-effect transistors). Transistors can be configured to provide variable resistor functions. A transistor can act as a variable resistor by modulating the resistance between its source and drain terminals. Transistors can be configured as switches. By applying a voltage to the gate terminal, the transistor can be switched on or off, controlling the flow of current between the source and drain. Transistors can be configured as amplifiers. Transistors can amplify signals by using a small input signal to control a larger output signal, effectively acting as a current amplifier.

In the illustrated example, circuit 300 may include capacitor 305 (e.g., AC coupling capacitor), transistor 310, transistor 315 (e.g., transistor switch, variable transistor), transistor 320, transistor 325, and capacitive load 330. As shown, circuit 300 may depict a schematic diagram of a hybrid circuit (e.g., hybrid circuit 205) that includes (a) flipped-voltage-follower (FVF) and source follower (SF) circuitry for higher common mode voltage; (b) continuous-time linear equalizer (CTLE) circuitry for a wider operational bandwidth (e.g., based on high-pass filter characteristics of the CTLE circuitry); and (c) an inner loop from a gate of transistor 320 to a node between transistor 310 and transistor 325.

In the illustrated example, transistor 310 may be connected to the input of circuit 300 and transistor 315 may be connected to transistor 310 and to the output of circuit 300. Transistor 320 may be connected to the output of circuit 300 and transistor 310. In some cases, a gate terminal of transistor 310 may be connected to the input of circuit 300 and capacitor 305. A drain terminal of transistor 310 may be connected to a source terminal of transistor 315. It is noted that the output of circuit 300 may indicate a logical value based on the input. The input of circuit 300 may include a voltage level of a memory cell.

In the illustrated example, transistor 315 may be configured as a variable resistor. In some cases, decreasing a resistor level of transistor 315 may decrease a direct current (DC) gain at the output of circuit 300. As shown, a gate terminal of transistor 315 may be connected to an enable control signal. A drain terminal of transistor 315 may be connected to the output of circuit 300, capacitor 305, and a source terminal of transistor 320. A drain terminal of transistor 320 may be connected to a positive supply voltage of circuit 300.

In the illustrated example, transistor 325 may be connected to transistor 310 and transistor 320. For example, a gate terminal of transistor 325 may be connected to an N-type metal oxide semiconductor (NMOS) bias voltage of circuit 300. A drain terminal of transistor 325 may be connected to a source terminal of transistor 310 and to a gate terminal of transistor 320. A source terminal of transistor 325 may be connected to ground.

As shown, capacitor 305 may be positioned between an input node of circuit 300 and an output node of circuit 300. Capacitor 305 may provide a CTLE function to circuit 300. Capacitor 305 may be used to allow AC signals to pass from the input node to the output node while blocking DC signals. For example, capacitor 305 may be configured as a high-pass filter, allowing AC signals to pass through while blocking DC signals. Thus, the AC coupling capacitor may provide an HPF function of circuit 300.

The CTLE circuitry of circuit 300 may include or may be based on capacitor 305 and transistor 315. Without capacitor 305 and transistor 315, circuit 300 may lose HPF functionality, resulting in the output of circuit 300 being based on the LPF characteristics of circuit 300, passing DC gain (e.g., relatively low frequency outputs) and attenuating AC gain (e.g., relatively high frequency output signals). However, circuit 300 may include capacitor 305 and transistor 315 to provide HPF functionality to circuit 300, which increases the operational bandwidth of circuit 300 by allowing some high frequencies (e.g., AC signals) and/or some low frequencies (e.g., DC signals) to pass through to the output of circuit 300 (e.g., RX circuit 215). Based on the HPF functionality of the CTLE components of circuit 300, together with the LPF characteristics of circuit 300, the operational bandwidth of circuit 300 is increased.

As shown, transistor 315 may be variable and may be enabled based on an enable control signal. In some cases, decreasing a setting of transistor 315 may decrease the passing of DC signals (e.g., attenuates relatively low frequencies).

The systems and methods described herein may provide flipped-voltage-follower (FVF) source follower (SF) with continuous-time linear equalizer (CTLE) for high-speed interface circuits. The systems and methods described may be based on an FVF SF system that provides High CM and a relatively wide bandwidth, with a CTLE (e.g., capacitor+variable resistor). In some cases, the circuits provided by the systems and methods described herein may provide an inner negative feedback loop, reducing the output impedance compared to circuits of other systems, which can result in a larger bandwidth compared to other systems.

In some cases, the input of circuit 300 (e.g., input voltage) may be relatively low (e.g., from ground to 0.25 V). The input may include a relatively high-frequency signal (e.g., 20 Gbps). The output of circuit 300 may include a relatively high-frequency signal (e.g., 20 Gbps). Based on the systems and methods described herein, the output voltage of circuit 300 may be high enough to operate an NMOS sampler at 20 Gbps.

In some systems, a source follower (SF) may have a level-up or level-down shifter function from input to output. Transconductance (g) may be denoted as a conductance, gₘ, where m is for mutual. The SF of some circuits may have 1/gₘ output impedance that provides a relatively large bandwidth for high frequency operation. However, the SF of some circuits may not have a CTLE function, which can provide a high-pass filter that compensates for the input channel loss based on the intrinsic low-pass filter characteristics of the circuit.

A DC gain at the output of circuit 300 may be determined based on the following equation:

$${Gain}_{DC} = \frac{1}{\frac{1}{Loop gain \times {g}_{m . IN}} + \frac{1}{{g}_{m . M 1}}}$$

As shown, the DC gain may be based on the gain of the inner loop (e.g., inner loop from a gate of transistor 320 to a node between transistor 310 and transistor 325), the conductance of transistor 310, and the conductance of transistor 315.

An alternating current (AC) gain at the output of circuit 300 may be determined from a quotient based on a capacitance of capacitor 305 and a load capacitance at the output of circuit 300. For example, the AC gain at the output of circuit 300 may be determined based on the following equation:

$${Gain}_{A C} = \frac{{C}_{AC}}{{C}_{AC} + {C}_{LOAD}}$$

In some cases, the DC gain of circuit 300 may be determined based on a setting of transistor 315. In some cases, a CTLE function of circuit 300 may be based on a difference or differential between the DC gain and AC gain of circuit 300.

The FVF circuitry of circuit 300 may include an enhanced SF with inner negative feedback for lower output impedance, which can result in larger bandwidth capacity. The increased bandwidth provided by circuit 300 can result in increased system performance in high-speed interface circuits. The increased bandwidth may be based on the smaller output impedance (e.g., 1/(gₘ*loop gain)). In some cases, the second pole of circuit 300 may be located in relatively high frequencies, or higher frequencies compared to other systems, providing better performance for high-speed interfaces.

Accordingly, circuit 300 may provide relatively high voltage levels for a subsequent sampler (e.g., NMOS input pairs of an RX circuit at output of circuit 300) and provide a HPF function to increase the operational bandwidth (e.g., increases flat gain region in frequency response) at the output of circuit 300.

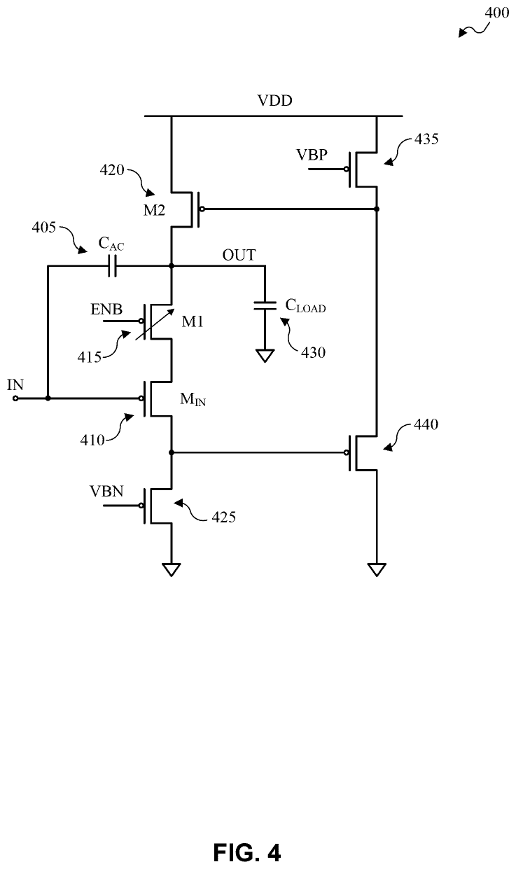

FIG. 4 illustrates an example circuit 400 in accordance with one or more implementations as described herein. In some configurations, one or more aspects of circuit 400 may be implemented by or in conjunction with a hybrid circuit (e.g., hybrid circuit 205). For example, circuit 400 may be based on or may incorporate a hybrid circuit based on flipped-voltage-follower (FVF) source follower (SF) continuous-time linear equalizer (CTLE) configured for high-speed interfaces (e.g., of memory systems, DDR, etc.). In some cases, circuit 400 may be an example of hybrid circuit 205 of FIG. 2.

As shown, circuit 400 may include capacitor 405 (e.g., AC coupling capacitor), transistor 410, transistor 415 (e.g., transistor switch, variable transistor), transistor 420, transistor 425, capacitive load 430, transistor 435, and transistor 440.

In some examples, circuit 400 may be a circuit of a memory device. As shown, coupling capacitor 405 may be connected to an input of circuit 400 and to an output of circuit 400. Transistor 410 may be connected to the input of circuit 400, and transistor 415 may be connected to transistor 410 and to the output of circuit 400. Transistor 420 may be connected to the output of circuit 400 and transistor 415. In some cases, the output of circuit 400 indicates a logical value of a memory cell of a memory device.

Transistor 425 may be connected to transistor 410. For example, a drain of transistor 425 may be connected to a source of transistor 410. A gate terminal of transistor 425 may be connected to an NMOS bias voltage of circuit 400 (e.g., VBN), and a source terminal of transistor 425 may be connected to ground.

As shown, a gate terminal of transistor 435 may be connected to a PMOS bias voltage of circuit 400 (e.g., VBP), and a drain terminal of transistor 435 and a drain terminal of transistor 420 may be connected to a positive supply voltage of circuit 400 (e.g., VDD). As shown, a drain terminal of transistor 440 may be connected to a gate of transistor 420 and a source of transistor 435. A gate terminal of transistor 440 may be connected to a source terminal of transistor 410 and a drain terminal of transistor 425. A source terminal of transistor 440 may be connected to ground.

In some examples, transistor 435 and transistor 440 may provide an additional source follower to circuit 400. In some cases, the additional source follower may improve setting a saturation region for transistor 420 (e.g., makes setting a saturation region of transistor 420 easier).

In some cases, the additional source follower may provide input range improvement for circuit 400. The input voltage range of a PMOS gate connection (e.g., VBP) may be relatively low. Based on a PMOS gate connection, the voltage may ramp up and peak out relatively quickly. As a result, the range of the linear slope may be relatively low. As shown, adding the additional source follower may include adding a node (e.g., gate node) between the gate of transistor 420 and the source of transistor 435. This gate node does not limit the input voltage range because the design separates this gate node from the node at the source of transistor 410 and drain of transistor 425, which connects to the gate of transistor 440. Accordingly, the input voltage range of circuit 400 is increased based on the additional source follower.

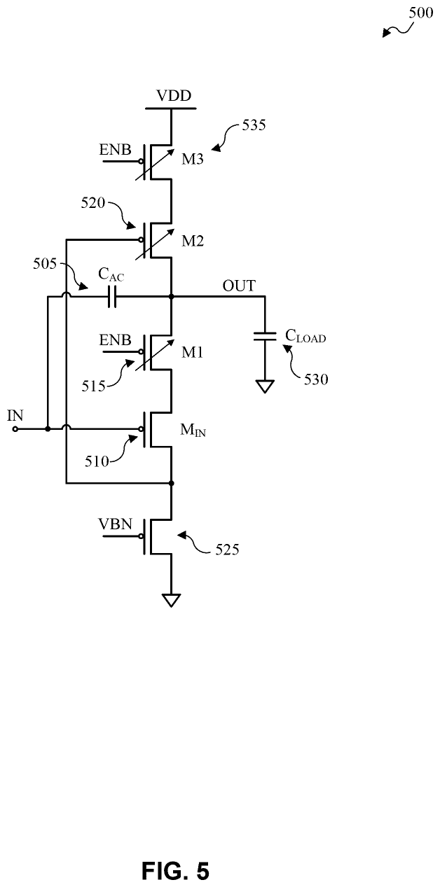

FIG. 5 illustrates an example circuit 500 in accordance with one or more implementations as described herein. In some configurations, one or more aspects of circuit 500 may be implemented by or in conjunction with a hybrid circuit (e.g., hybrid circuit 205). For example, circuit 500 may be based on or may incorporate a hybrid circuit based on flipped-voltage-follower (FVF) source follower (SF) continuous-time linear equalizer (CTLE) configured for high-speed interfaces (e.g., of memory systems, DDR, etc.). In some cases, circuit 500 may be an example of hybrid circuit 205 of FIG. 2.

In the illustrated example, circuit 500 may include capacitor 505 (e.g., AC coupling capacitor), transistor 510, transistor 515 (e.g., transistor switch, variable transistor), transistor 520, transistor 525, capacitive load 530, and transistor 535 (e.g., transistor switch). Circuit 500 may depict a schematic diagram of a hybrid circuit (e.g., hybrid circuit 205) that includes (a) flipped-voltage-follower (FVF) and source follower (SF) circuitry for higher common mode voltage; (b) continuous-time linear equalizer (CTLE) circuitry for a wider operational bandwidth (e.g., based on high-pass filter characteristics of the CTLE circuitry); and (c) an inner loop from a gate of transistor 520 to a node between transistor 510 and transistor 525.

In some examples, circuit 500 may be part of a memory system (e.g., DDR, DRAM). As shown, capacitor 505 may be connected to an input of circuit 500 and to an output of circuit 500. Also, transistor 510 may be connected to the input of circuit 500. In some cases, a source terminal of transistor 515 may be connected to a drain of transistor 510. As shown, a drain terminal of transistor 515 may be connected to the capacitor 505, the output of circuit 500, and a source terminal of transistor 520.

As shown, a source terminal of transistor 520 may be connected to the output of circuit 500 and a drain terminal of transistor 515. The input of circuit 500 may include a voltage level of a memory cell. The output of circuit 500 may indicate a logical value of the memory cell (e.g., to an RX circuit such as RX circuit 215).

As shown, a gate terminal of transistor 525 may be connected to an N-type metal oxide semiconductor (NMOS) bias voltage of circuit 500 (e.g., VBN). A drain terminal of transistor 525 may be connected to a source terminal of transistor 510 and to a gate terminal of transistor 520 (e.g., inner loop). A source terminal of transistor 525 may be connected to ground.

As shown, a gate terminal of transistor 535 may be connected to an enable control signal of circuit 500. A drain terminal of transistor 535 may be connected to a positive supply voltage of circuit 500 (e.g., VDD). A source terminal of transistor 535 may be connected to a drain of transistor 520.

As shown, transistor 520 and transistor 535 may be variable transistors, in addition to transistor 515. In some cases, a setting of transistor 520 and/or a setting of transistor 535 may track a setting of transistor 515. In some cases, aspects of circuit 500 may improve a gain linearity of circuit 500. For example, adding transistor 535 and making transistor 520 and transistor 535 variable increases a linearity of the gain of circuit 500 (e.g., increases the range of the linear slope in the output of circuit 500). In some cases, when a setting of transistor 515 is modified, the step may be non-linear. Accordingly, transistor 535 may be variable and may be added between transistor 520 and VDD, enabling transistor 535 to increase the linear step of AC gain (e.g., increasing gain linearity of circuit 500) when transistor 515, transistor 520, and/or transistor 535 are modified. Increasing the gain linearity of circuit 500 may improve the operational bandwidth of circuit 500. Accordingly, adding transistor 535 to circuit 500, making transistor 520 variable, and making transistor 535 variable increases the operational bandwidth of circuit 500.

In the examples described herein, the configurations and operations are example configurations and operations, and may involve various additional configurations and operations not explicitly illustrated. In some examples, one or more aspects of the illustrated configurations and/or operations may be omitted. In some embodiments, one or more of the operations may be performed by components other than those illustrated herein. Additionally, or alternatively, the sequential and/or temporal order of the operations may be varied.

Certain embodiments may be implemented in one or a combination of hardware, firmware, and software. Other embodiments may be implemented as instructions stored on a computer-readable storage device, which may be read and executed by at least one processor to perform the operations described herein. A computer-readable storage device may include any non-transitory memory mechanism for storing information in a form readable by a machine (e.g., a computer). For example, a computer-readable storage device may include read-only memory (ROM), random-access memory (RAM), magnetic disk storage media, optical storage media, flash-memory devices, and other storage devices and media.

The word “exemplary” is used herein to mean “serving as an example, instance, or illustration.” Any embodiment described herein as “exemplary” is not necessarily to be construed as preferred or advantageous over other embodiments.

As used within this document, the term “communicate” is intended to include transmitting, or receiving, or both transmitting and receiving. Similarly, the bidirectional exchange of data between two devices (both devices transmit and receive during the exchange) may be described as ‘communicating’, when only the functionality of one of those devices is being claimed. The term “communicating” as used herein with respect to wired and/or wireless communication signals includes transmitting the wired and/or wireless communication signals and/or receiving the wired and/or wireless communication signals. For example, a communication unit, which is capable of communicating wired and/or wireless communication signals, may include a wired/wireless transmitter to transmit communication signals to at least one other communication unit, and/or a wired/wireless communication receiver to receive the communication signal from at least one other communication unit.

Some embodiments may be used in conjunction with various devices and systems, for example, a Personal Computer (PC), a desktop computer, a mobile computer, a laptop computer, a notebook computer, a tablet computer, a server computer, a handheld computer, a handheld device, a Personal Digital Assistant (PDA) device, a handheld PDA device, an on-board device, an off-board device, a hybrid device, a vehicular device, a non-vehicular device, a mobile or portable device, a consumer device, a non-mobile or non-portable device, a wireless communication station, a wireless communication device, a wireless Access Point (AP), a wired or wireless router, a wired or wireless modem, a video device, an audio device, an audio-video (A/V) device, a wired or wireless network, a wireless area network, a Wireless Video Area Network (WVAN), a Local Area Network (LAN), a Wireless LAN (WLAN), a Personal Area Network (PAN), a Wireless PAN (WPAN), and the like.

Although an example processing system has been described above, embodiments of the subject matter and the functional operations described herein can be implemented in other types of digital electronic circuitry, or in computer software, firmware, or hardware, including the structures disclosed in this specification and their structural equivalents, or in combinations of one or more of them.

Embodiments of the subject matter and the operations described herein can be implemented in digital electronic circuitry, or in computer software, firmware, or hardware, including the structures disclosed in this specification and their structural equivalents, or in combinations of one or more of them. Embodiments of the subject matter described herein can be implemented as one or more computer programs, i.e., one or more components of computer program instructions, encoded on computer storage medium for execution by, or to control the operation of, information/data processing apparatus. Alternatively, or in addition, the program instructions can be encoded on an artificially-generated propagated signal, for example, a machine-generated electrical, optical, or electromagnetic signal, which is generated to encode information/data for transmission to suitable receiver apparatus for execution by an information/data processing apparatus.

The operations described herein can be implemented as operations performed by an information/data processing apparatus on information/data stored on one or more computer-readable storage devices or received from other sources.

While this specification contains many specific embodiment details, these should not be construed as limitations on the scope of any embodiment or of what may be claimed, but rather as descriptions of features specific to particular embodiments. Certain features that are described herein in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described. Other embodiments are within the scope of the following claims. In some cases, the actions recited in the claims can be performed in a different order and still achieve desirable results. In addition, the processes depicted in the accompanying figures do not necessarily require the particular order shown, or sequential order, to achieve desirable results. In certain embodiments, multitasking and parallel processing may be advantageous.

Many modifications and other examples as set forth herein will come to mind to one skilled in the art to which these embodiments pertain, having the benefit of the teachings presented in the foregoing descriptions and the associated drawings. Therefore, it is to be understood that the embodiments are not to be limited to the specific embodiments disclosed and that modifications and other embodiments are intended to be included within the scope of the appended claims. Although specific terms are employed herein, they are used in a generic and descriptive sense only and not for purposes of limitation.

What is claimed:

1. A circuit comprising:
a first capacitor connected to an input of the circuit and to an output of the circuit;
a first transistor connected to the input of the circuit;
a second transistor connected to the first transistor and to the output of the circuit;
a third transistor connected to the output of the circuit and the first transistor; and
the output of the circuit indicating a logical value based on the input.

2. The circuit of claim 1, wherein:
a gate terminal of the first transistor is connected to the input of the circuit and the first capacitor, and
a drain terminal of the first transistor is connected to a source terminal of the second transistor.

3. The circuit of claim 1, wherein the second transistor is configured as a variable resistor.

4. The circuit of claim 1, wherein decreasing a resistor level of the second transistor decreases a direct current (DC) gain at the output of the circuit.

5. The circuit of claim 1, wherein:
a gate terminal of the second transistor is connected to an enable control signal, and
a drain terminal of the second transistor is connected to the output of the circuit, the first capacitor, and a source terminal of the third transistor.

6. The circuit of claim 1, wherein a drain terminal of the third transistor is connected to a positive supply voltage of the circuit.

7. The circuit of claim 1, further comprising a fourth transistor connected to the first transistor and the third transistor.

8. The circuit of claim 7, wherein:
a gate terminal of the fourth transistor is connected to an N-type metal oxide semiconductor (NMOS) bias voltage of the circuit,
a drain terminal of the fourth transistor is connected to a source terminal of the first transistor and to a gate terminal of the third transistor, and
a source terminal of the fourth transistor is connected to ground.

9. The circuit of claim 1, wherein the first capacitor is configured as a high-pass filter that attenuates direct current (DC) signals from the input of the circuit to the output of the circuit and allows alternating current (AC) signals to pass from the input of the circuit to the output of the circuit.

10. The circuit of claim 1, wherein the input of the circuit includes a voltage level of a memory cell.

11. The circuit of claim 1, wherein an alternating current (AC) gain at the output of the circuit is determined from a quotient based on a capacitance of the first capacitor and a load capacitance at the output of the circuit.

12. A circuit of a memory device comprising:
a first capacitor connected to an input of the circuit and to an output of the circuit;
a first transistor connected to the input of the circuit;
a second transistor connected to the first transistor and to the output of the circuit;
a third transistor connected to the output of the circuit and the first transistor;
a fourth transistor connected to the first transistor; and
the output of the circuit indicating a logical value of a memory cell of the memory device.

13. The circuit of claim 12, wherein:
a gate terminal of the fourth transistor is connected to an N-type metal oxide semiconductor (NMOS) bias voltage of the circuit, and
a source terminal of the fourth transistor is connected to ground.

14. The circuit of claim 12, further comprising a fifth transistor, wherein:
a gate terminal of the fifth transistor is connected to a P-type metal oxide semiconductor (PMOS) bias voltage of the circuit, and
a drain terminal of the fifth transistor and a drain terminal of the third transistor are connected to a positive supply voltage of the circuit.

15. The circuit of claim 14, further comprising a sixth transistor, wherein:
a drain terminal of the sixth transistor is connected to a gate of the third transistor and a source of the fifth transistor;
a gate terminal of the sixth transistor is connected to a source of the first transistor and the drain of the fourth transistor, and
a source terminal of the sixth transistor is connected to ground.

16. A memory system comprising a circuit, the circuit comprising:
a first capacitor connected to an input of the circuit and to an output of the circuit;
a first transistor connected to the input of the circuit;
a second transistor connected to the first transistor and to the output of the circuit;
a third transistor connected to the output of the circuit and the second transistor; and
the output of the circuit indicating a logical value of a memory cell.

17. The circuit of claim 16, further comprising a fourth transistor, wherein:
a gate terminal of the fourth transistor is connected to an N-type metal oxide semiconductor (NMOS) bias voltage of the circuit,
a drain terminal of the fourth transistor is connected to a source terminal of the first transistor and to a gate terminal of the third transistor, and
a source terminal of the fourth transistor is connected to ground.

18. The circuit of claim 16, further comprising a fifth transistor, wherein:
a gate terminal of the fifth transistor is connected to an enable control signal,
a drain terminal of the fifth transistor is connected to a positive supply voltage of the circuit, and
a source terminal of the fifth transistor is connected to a drain of the third transistor.

19. The circuit of claim 18, wherein the third transistor and the fifth transistor are configured as respective variable resistors.

20. The circuit of claim 16, wherein the input of the circuit includes a voltage level of a memory cell.
